(19) United States
(12) Patent Application Publication
(10) Pub. No.: US 2024/0257874 A1
(43) Pub. Date: Aug. 1, 2024

(54) NON-VOLATILE MEMORY CELL STRUCTURES AND METHODS OF MANUFACTURING THEREOF

(71) Applicant: Taiwan Semiconductor Manufacturing Company, Ltd., Hsinchu (TW)

(72) Inventors: Shih-Hsien Chen, Zhubei City (TW); Chun-Yao Ko, Hsinchu City (TW); Liang-Tai Kuo, Zhudong Township (TW); YingKit Felix Tsui, Cupertino, CA (US)

(73) Assignee: Taiwan Semiconductor Manufacturing Company, Ltd., Hsinchu (TW)

(21) Appl. No.: 18/103,350

(22) Filed: Jan. 30, 2023

(51) Int. Cl. G11C 16/04; G11C 16/24; H10B 41/10; H10B 41/23; H10B 41/35; H10B 41/70

(52) U.S. Cl. CPC G11C 16/0483; G11C 16/24; H10B 41/10; H10B 41/23; H10B 41/35; H10B 41/70

(57) ABSTRACT

A memory device includes a first well region, a second well region, and third well regions. The second well region is interposed between the first region and the third well regions, and the third well regions are separated from one another. The memory device includes floating gates disposed over the first to third well regions, wherein each of the floating gates continuously extends from the first well region to a corresponding one of the third well regions. The memory device includes a bit line write region disposed within the second well region. The bit line write region comprises first source/drain regions on opposite sides of each floating gate. The memory device includes a bit line read region disposed within the second well region and spaced from the bit line write region. The bit line read region comprises second source/drain regions on the opposite sides of each floating gate.

### BACKGROUND

In general, modern electronic devices include electronic memory devices that can store data. Electronic memory devices typically include volatile memory devices or non-volatile memory (NVM) devices. A volatile memory device can store data while it is powered, while a NVM device is able to keep data when power is removed. Multi-time programmable (MTP) cells are one promising candidate for the next generation NVM devices. The MTP cells may be integrated with bipolar complementary metal-oxide-semiconductor (CMOS) double-diffused metal-oxide-semiconductor (DMOS) (BCD) technology and/or high voltage (HV) CMOS technology in system-on-chip (SoC) applications. Among other things, integrating the MTP cells with HV technology or BCD technology finds application in the internet of things (IoT), power management, smart cards, microcontroller units (MCUs), and automotive devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example layout of a memory cell, in accordance with some embodiments.

FIG. 2 illustrates a cross-sectional view of the memory cell of FIG. 1, in accordance with some embodiments.

FIG. 3 illustrates another cross-sectional view of the memory cell of FIG. 1, in accordance with some embodiments.

FIG. 4 illustrates a schematic diagram of a circuit including a number of memory cells, in accordance with some embodiments.

FIG. 5 illustrates an example circuit diagram of the memory cell of FIGS. 1-3, in accordance with some embodiments.

FIG. 6 illustrates a Table corresponding to some operation conditions applied to one or more of the memory cells of FIGS. 1-3, in accordance with various embodiments.

FIG. 7 illustrates an example layout of a NAND memory string that includes a plural number of the memory cells of FIGS. 1-3, in accordance with various embodiments.

FIG. 8 illustrates a flow chart of an example method for forming a memory device, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip may include non-volatile memory (NVM) device that is configured to retain stored information even when the integrated chip is not powered. A multi-time programmable (MTP) cell is one form of the NVM device that may include a number of transistors and a number of capacitors operatively coupled to one another. For example, the MTP cell may include a storage transistor, a selector transistor, a coupling capacitor, and a tunneling capacitor, such that the MTP cell is in a two-transistor-two-capacitor (2T2C) configuration. The coupling capacitor, tunneling capacitor, and the storage transistor may share a floating gate. Further, a bit line may be coupled to a bit line active region disposed in a substrate underlying the floating gate. The floating gate may be separated from the substrate by a gate dielectric structure. The bit line active region is a discrete region of the substrate and is a part of the storage transistor. A proper bias voltage may be applied to the bit line active region to read a data value of the MTP cell or to write (e.g., erase or program) a data value of the MTP cell.

During operation, the MTP cell may be programmed and/or erased by Fowler-Nordheim (FN) tunneling. In an erase operation, stored electric charge within the floating gate may be removed from the floating gate to a first electrode of the tunneling capacitor by FN tunneling, thereby placing the MTP cell in a high resistance state. In a program operation, charge carriers (e.g., electrons) may be injected from the bit line active region into the floating gate by FN tunneling, thereby placing the MTP cell in a low resistance state. In a read operation, proper bias conditions are applied to the MTP cell such that a data state of the MTP cell may be accessed at a source/drain region within the bit line active region. However, during the erase or program operation, the charge carriers may be trapped within the gate dielectric structure and/or damage a crystal lattice of the gate dielectric structure. This in part may result in device failure after a number of programming operations, inaccurate read operations, and/or reduced device reliability. The inaccurate read operations may, for example, occur because the trapped charge carriers within the gate dielectric structure may be mistaken as a data state of the MTP cell. For example, in an application utilizing 110 nanometer (nm) transistors or less, the MTP cell may fail due to damage in the gate dielectric structure after about 10,000 program operations. In yet another example, in a high voltage application with 40 nm (or less) transistor(s), the MTP cell may fail due to damage to the gate dielectric structure after about 1,000 program operations.

Accordingly, the present disclosure provides various embodiments of a memory device that includes a number of NVM cells, each of which has a four-transistor-two-capacitor (4T2C) configuration with increased endurance and reliability. Further, the NVM cells may be coupled to one another as a number of NAND memory strings, which can advantageously improve (e.g., shrink) a total area occupied by the 4T2C NVM cells. For example, each of the NVM cells includes a coupling capacitor, a tunneling capacitor, a first storage transistor, a second storage transistor, a first selector transistor, and a second selector transistor. The coupling capacitor, tunneling capacitor, first storage transistor, and second storage transistor share a floating gate that overlies a substrate. A gate dielectric structure is disposed between the floating gate and the substrate. The first storage and selector transistors include a bit line write active region, while the second storage and selector transistors include a bit line read active region. The bit line read and write active regions are discrete regions of the substrate laterally offset from one another. The NVM cell can perform a program operation such that FN tunneling occurs between the floating gate and the bit line write active region. Further, the NVM cell can perform a read operation such that a data state of the NVM cell may be accessed at the second selector transistor and within the bit line read active region. Thus, the FN tunneling utilized in the program operation is isolated from the bit line read active region such that the gate dielectric structure between the floating gate and the bit line read active region is not damaged during the program operation. This in part mitigates and/or eliminates damage to the gate dielectric structure that is adjacent to the bit line read active region, thereby increasing a number of program and/or erase operations that may be performed on the NVM cell, decreasing inaccurate read operations, and/or increasing an endurance of the NVM cell. In addition, a subset of the NVM cells can form a corresponding NAND memory string. For example, such a subset of the NVM cells can share a common bit line read active region and a common bit line write active region. As such, a total area occupied by the NVM cells can be advantageously reduced, which can in turn make the disclosed memory device suitable to be utilized in a variety of applications.

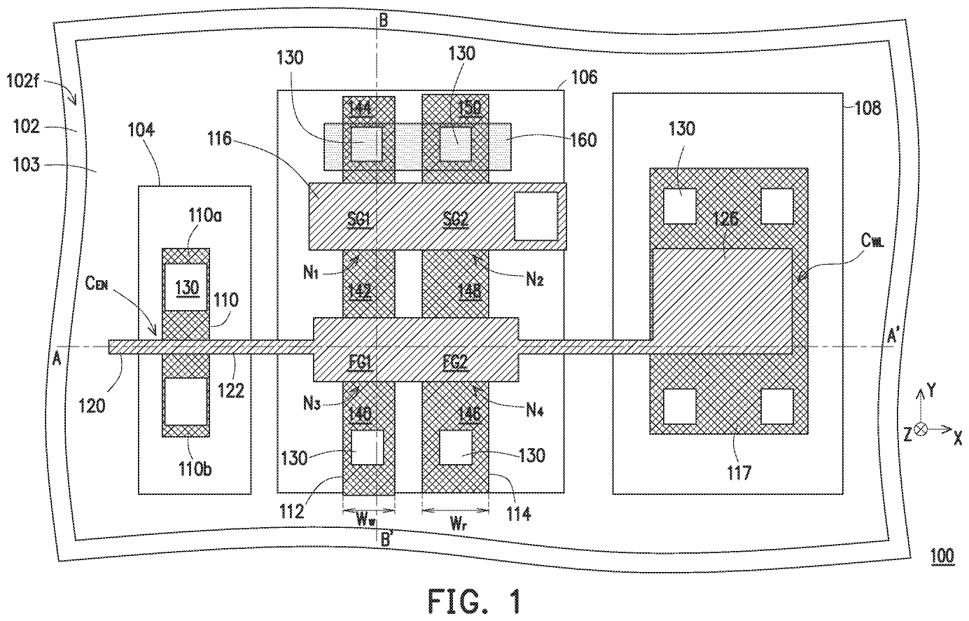

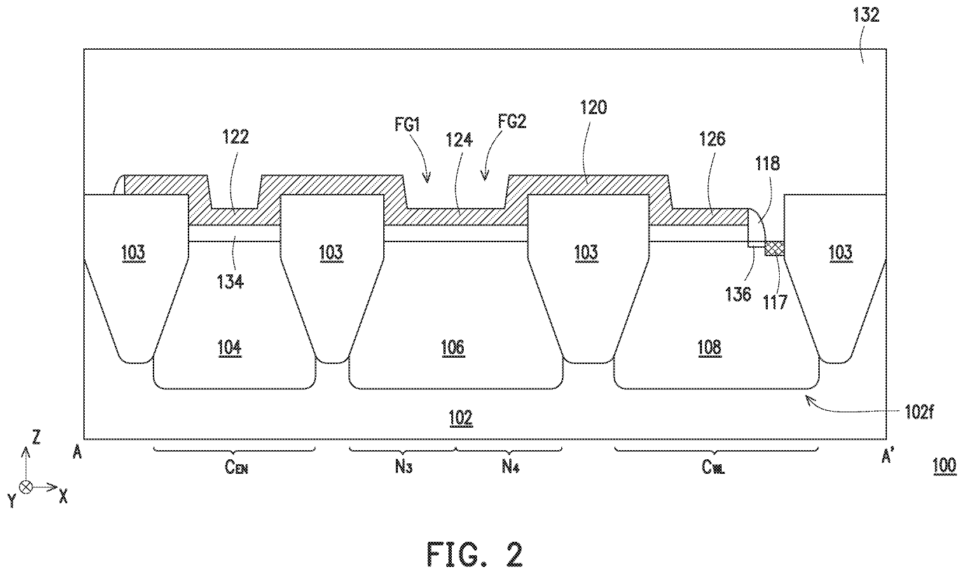

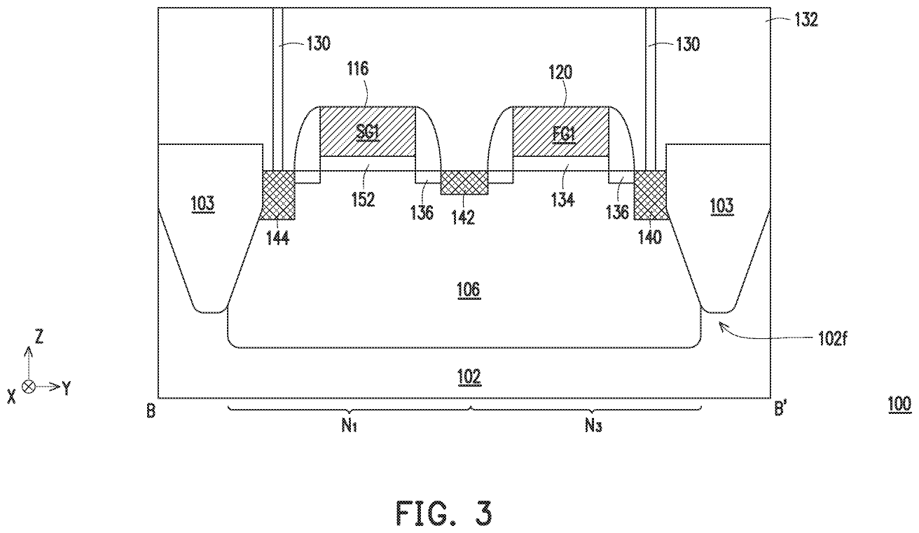

FIGS. 1, 2, and 3 illustrate various views of some embodiments of a memory cell 100 including a floating gate (FG) 120 overlying a bit line write (BL_{W}) region 112 and a bit line read (BL_{R}) region 114. In brief overview, FIG. 1 illustrates an example layout of the memory cell 100 from a front-side 102f of a substrate 102; FIG. 2 illustrates a cross-sectional view of the memory cell 100 taken along line A-A′, as indicated in FIG. 1; and FIG. 3 illustrates another cross-sectional view of the memory cell 100 taken along line B-B′ of FIG. 1, as indicated in FIG. 1.

The memory cell 100 includes select transistors N₁ and N₂, storage transistors N₃ and N₄, and capacitors C_{EN} and C_{WL}, which is sometimes referred to as a four-transistor and two-capacitor (4T2C) configuration. For example in FIG. 1, the memory cell 100 includes conductive features overlying the front-side 102f of the substrate 102 and doped regions disposed within the substrate 102. The conductive features include the FG 120 and a select gate (SG) 116. The FG 120 and the SG 116 overlie the front-side 102f of the substrate 102. The FG 120 is separated from the front-side 102f of the substrate 102 by a dielectric structure 134 (which is shown in the cross-sectional view of FIGS. 2-3) and the SG 116 is separated from the front-side 102f of the substrate 102 by a select gate dielectric structure 152 (which is also shown in the cross-sectional view of FIGS. 2-3). Further, a sidewall spacer structure 118 (which is omitted in FIG. 1 for clarity, but is shown in the cross-sectional view of FIGS. 2-3) laterally surrounds sidewalls of the FG 120 and the SG 116, respectively. An isolation structure 103 extends from the front-side 102f of the substrate 102 to a point below the front-side 102f. As shown in FIGS. 2-3, an interconnect dielectric structure 132 overlies the FG 120, the SG 116, and the front-side 102f of the substrate 102. In some embodiments, the doped regions include a first well region 104, a second well region 106, and a third well region 108. Along a first lateral direction (e.g., the X direction), the FG 120 continuously laterally extends over the first well region 104, the second well region 106, and the third well region 108. The FG 120 may include a first FG portion 122 overlying the first well region 104, a second FG portion 124 overlying the second well region 106, and a third FG portion 126 overlying the third well region 108. The SG 116 overlies the second well region 106. In some embodiments, the SG 116 and the FG 120 may, for example, each be or comprise a conductive material, such as polysilicon, or another suitable conductive material.

In some embodiments, the first, second, and third well regions 104, 106, 108 are laterally offset from one another by a non-zero distance and/or are discrete from one another along the X direction. The substrate 102 may, for example, be or comprise a bulk semiconductor substrate (e.g., a bulk silicon substrate), a silicon-on-insulator (SOI) substrate, or another suitable substrate material and/or may comprise a first doping type (e.g., p-type). The first well region 104 is a discrete region of the substrate 102 and comprises a second doping type (e.g., n-type) opposite the first doping type. The first doping type is p-type and the second doping type is n-type, or vice versa. The second well region 106 is a discrete region of the substrate 102 and comprises the first doping type (e.g., p-type) with a higher doping concentration than the substrate 102. The third well region 108 is a discrete region of the substrate 102 and comprises the second doping type (e.g., n-type).

A first capacitor active region 110 is disposed within the first well region 104 and may comprise the second doping type (e.g., n-type). Thus, in some embodiments, the first capacitor active region 110 comprises a same doping type as the first well region 104. This facilitates the first capacitor active region 110 (and/or the first well region 104) being configured as a first electrode (or plate) of the first capacitor C_{EN}. The first FG portion 122 of the FG 120 overlying the first capacitor active region 110 and/or the first well region 104 is configured as a second electrode (or plate) of the first capacitor C_{EN}. Thus, a region in which the first FG portion 122 overlaps the first capacitor active region 110 and/or the first well region 104 determines a capacitance of the first capacitor C_{EN}. Further, a region of the dielectric structure 134 disposed between the first FG portion 122 and the first capacitor active region 110 and/or the first well region 104 may be configured as a first capacitor dielectric layer of the first capacitor C_{EN}. The first capacitor active region 110 may include contact regions 110a and 110b disposed on opposite sides of the first FG portion 122. In some embodiments, a conductive via 130 is disposed over the contact region 110a of the first capacitor active region 110 and is electrically coupled to an erase node (EN). In some embodiments, the erase node EN may be electrically coupled to an erase line configured to perform an erase operation on the memory cell 100.

In some embodiments, the bit line write (BL_{W}) region 112 and the bit line read (BL_{R}) region 114 are both disposed within the second well region 106 and are laterally offset from one another by a non-zero distance along the X direction. The bit line write and read regions 112, 114 respectively comprise the second doping type (e.g., n-type), such that the bit line write and read regions 112, 114 comprise a doping type opposite the second well region 106. Thus, depletion regions may respectively from around the bit line write and read regions 112, 114, thereby facilitating electrical isolation between the bit line write and read regions 112, 114.

In various embodiments, the second well region 106, the bit line write region 112, and the SG 116 are configured to form the first select transistor N₁. The second well region 106, the bit line read region 114, and the SG 116 are configured to form the second select transistor N₂. The second well region 106, the bit line write region 112, and the second FG portion 124 are configured to form the first storage transistor N₃. The second well region 106, the bit line read region 114, and the second FG portion 124 are configured to form the second storage transistor N₄. The transistor N₁-N₄ may respectively, for example, be or comprise a metal oxide semiconductor field effect transistor (MOSFET), a high voltage transistor, a bipolar junction transistor (BJT), an n-channel metal oxide semiconductor (nMOS) transistor, a p-channel metal oxide semiconductor (pMOS) transistor, or another suitable transistor. In some embodiments, the transistors N₁-N₄ are each configured as an nMOS transistor. In some other embodiments, the transistors N₁-N₄ are each configured as a pMOS transistor.

The second FG portion 124 of the FG 120 divides the bit line write region 112 into a first source/drain region 140 and a second source/drain region 142. In some embodiments, a segment of the second FG portion 124 disposed between the first and second source/drain regions 140, 142 is configured as a first floating gate (FG₁) of the first storage transistor N₃. The SG 116 is disposed laterally between the second source/drain region 142 and a third source/drain region 144 of the bit line write region 112. A segment of the SG 116 disposed between the second source/drain region 142 and the third source/drain region 144 is configured as a first select gate (SG₁) of the first select transistor N₁. The second FG portion 124 of the FG 120 divides the bit line read region 114 into a fourth source/drain region 146 and a fifth source/drain region 148. A segment of the second FG portion 124 disposed between the fourth and fifth source/drain regions 146, 148 is configured as a second floating gate (FG₂) of the second storage transistor N₄. The SG 116 is disposed laterally between the fifth source/drain region 148 and a sixth source/drain region 150 of the bit line read region 114. A segment of the SG 116 disposed between the fifth and sixth source/drain regions 148, 150 is configured as a second select gate (SG₂) of the second select transistor N₂.

The source/drain regions 140-150 may, for example, respectively be configured as a source or a drain region for a corresponding transistor. The second source/drain region 142 is configured as a first common source/drain region shared by the first select transistor N₁ and the first storage transistor N₃, such that the first select transistor N₁ and the first storage transistor N₃ are serially coupled. The fifth source/drain region 148 is configured as a second common source/drain region shared by the second select transistor N₂ and the second storage transistor N₄, such that the second select transistor N₂ and the second storage transistor N₄ are serially coupled.

In some embodiments, a selector line is electrically coupled to the SG 116 by way of an overlying conductive via 130. The selector line may be configured to apply appropriate bias conditions to the SG 116 during an erase operation, a program operation, and/or a read operation performed on the memory cell 100. A source line (SL) 160 is electrically coupled to the third and/or sixth source/drain regions 144, 150 by way of conductive vias 130. Thus, the third and sixth source/drain regions 144, 150 may be electrically coupled together. The SL 160 may be configured to apply appropriate bias conditions to source/drain regions of the first and second select transistors N₁, N₂ during an erase operation, a program operation, and/or a read operation performed on the memory cell 100.

In some embodiments, a first bit line (BL₁) is electrically coupled to the first source/drain region 140 of the first storage transistor N₃ by way of a conductive via 130. The BL₁ may be electrically coupled to support circuitry (e.g., a bit line decoder, a word line decoder, a control unit such as a micro controller unit (MCU), etc.) (not shown) such as a bit line decoder (not shown) configured to perform a write operation (i.e., a program operation) on the memory cell 100. A second bit line (BL₂) is electrically coupled to the fourth source/drain region 146 of the second storage transistor N₄ by way of a conductive via 130. The BL₂ may be electrically coupled to the support circuitry such as a bit line decoder configured to perform a read operation on the memory cell 100. In some embodiments, a width W_{w} of the bit line write region 112 is less than a width Wᵣ of the bit line read region 114. In some other embodiments, the width W_{w} of the bit line write region 112 is equal to the width Wᵣ of the bit line read region 114 (not shown).

In some embodiments, a second capacitor active region 117 is disposed within the third well region 108 and may comprise the second doping type (e.g., n-type). Thus, the second capacitor active region 117 comprises a same doping type as the third well region 108. This facilitates the second capacitor active region 117 and/or the third well region 108 being configured as a first electrode (or plate) of the second capacitor C_{WL}. The third FG portion 126 of the FG 120 overlying the second capacitor active region 117 and/or the third well region 108 is configured as a second electrode (or plate) of the second capacitor C_{WL}. Thus, a region in which the third FG portion 126 overlaps the second capacitor active region 117 and/or the third well region 108 determines a capacitance of the second capacitor C_{WL}. Further, a region of the dielectric structure 134 disposed between the third FG portion 126 and the second capacitor active region 117 and/or the third well region 108 may be configured as a second capacitor dielectric layer of the second capacitor C_{WL}. In some embodiments, one or more conductive vias 130 overlie the second capacitor active region 117 and may be electrically coupled to a word line (WL). In some embodiments, the WL may be electrically coupled to support circuitry, such as a word line decoder (not shown) that is configured to perform a read and/or write operation on the memory cell 100. In some embodiments, an area of the first FG portion 122 over the first capacitor active region 110 is less than an area of the third FG portion 126 over the second capacitor active region 117, such that the capacitance of the first capacitor C_{EN} is less than the capacitance of the second capacitor C_{WL}.

In some embodiments, lightly doped regions 136 (FIGS. 2-3) are disposed within the substrate 102 and may be disposed between the FG 120 and/or the SG 116 and an adjacent active region (e.g., the second capacitor active region 117, the bit line write and/or read regions 112, 114). The lightly doped region 136 comprises a same doping type as the adjacent active region (e.g., the second doping type). The lightly doped region 136 may have a lower doping concentration than the adjacent active region (e.g., the second capacitor active region 117). The lightly doped region 136 may be a part of an adjacent source/drain region.

In some embodiments, during a programing operation performed on the memory cell 100, charge carriers (e.g., electrons) may be injected from the first source/drain region 140 of the bit line write region 112 to the FG 120 by Fowler-Nordheim (FN) tunneling. As such, the programing operation may damage a segment of the dielectric structure 134 disposed between the first floating gate FG₁ and the second well region 106 and/or the bit line write region 112. During a read operation performed on the memory cell 100, a data state of the memory cell 100 may be accessed at the sixth source/drain region 150 of the bit line read region 114 by way of the second storage transistor N₄ and the second select transistor N₂. In such embodiments, because the bit line write region 112 and the bit line read region 114 are laterally offset from one another by a non-zero distance, the damage to the dielectric structure 134 by the programing operation may not adversely affect the read operation performed on the memory cell 100. For example, a segment of the dielectric structure 134 disposed between the second floating gate FG₂ and the second well region 106 and/or the bit line read region 114 may not be damaged by the programing operation. This in turn may mitigate inaccurate read operations, increase a number of write operations (i.e., erase and/or program operations) that may be performed on the memory cell 100, and/or increase a reliability of the memory cell 100.

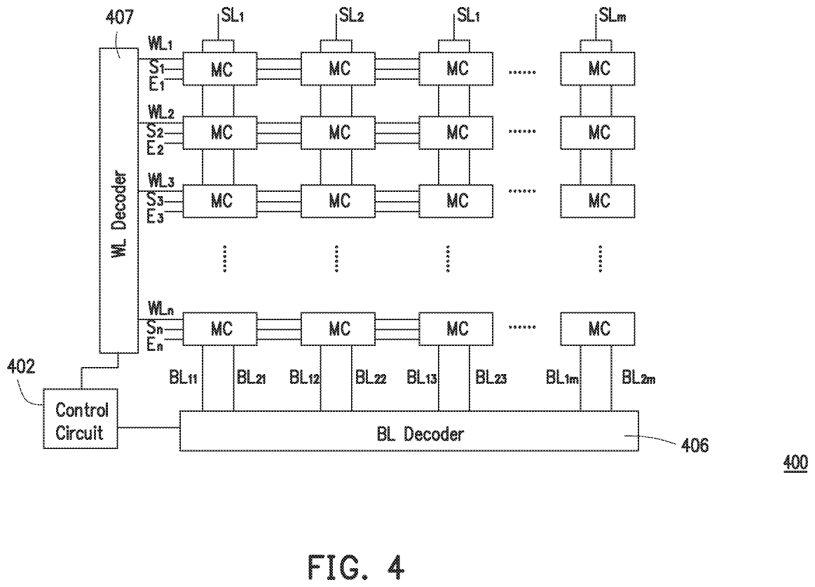

FIG. 4 illustrates a schematic diagram of a circuit 400 including a number of memory cells (MCs) arranged as a number of rows and a number of columns. Each of the MCs shown in FIG. 4 may be implemented as the memory cell 100 (FIG. 1), such that each MC has a bit line write region (e.g., 112 of FIG. 1) laterally offset from a bit line read region (e.g., 114 of FIG. 1) and are each in a 4T2C configuration, in various embodiments.

As shown, the circuit 400 includes the MCs arranged over plural pairs of bit lines BL₁₁₋₂ₘ (m is an integer), source lines SL₁₋ₘ, word lines WL₁₋ₙ (n is an integer), selector lines S₁₋ₙ, and erase lines E₁₋ₙ. The circuit 400 further includes a control circuit 402, a word line (WL) decoder 404, and a bit line (BL) decoder 406. Further, the MCs are arranged within a memory array comprising rows and columns, where each row includes a corresponding one of the word lines (e.g., one of WL₁ to WLₙ), and each column includes a corresponding one of the bit line pairs (e.g., one of the pairs, BL₁₁ and BL₂₁ to BL₁ₘ and BL₂ₘ). As such, MCs within a row of the memory array are operably coupled to a word line WL₁₋ₙ while MCs within a column of the memory array are operably coupled to a bit line pair BL₁₁₋₂ₘ. This causes the MCs to be respectively associated with an address defined by an intersection of a WL and a BL pair. In some embodiments, each of the MCs may be configured as a non-volatile memory (NVM) multi-time programmable (MTP) cell, such that a resistance value of each MC may be set and/or reset between at least two resistance values. Additionally, a resistance value of each NVM MTP cell may be set and/or reset multiple times (e.g., greater than 10,000 set and/or reset operations may be performed on each cell).

The memory array is electrically coupled to support circuitry that is configured to perform a write operation (i.e., an erase operation and/or a program operation) and/or a read operation on the MCs. For example, the support circuitry can include the control circuit 402, the WL decoder 404, and the BL decoder 406. The control circuit 402 is a microprocessor circuit. The selector lines S₁₋ₙ and/or the erase lines E₁₋ₙ may be electrically coupled to the control circuit 402 and/or the WL decoder 404. The control circuit 402 is configured to control the WL decoder 404 and/or the BL decoder 406, for example, the control circuit 402 may supply an address (e.g., the address is associated with a single MC in the memory array) to the WL decoder 404 and/or the BL decoder 406. The WL decoder 404 is configured to selectively apply a signal (e.g., a current and/or a voltage) to one or more of the word lines WL₁₋ₙ, one or more of the erase lines E₁₋ₙ, and/or one or more of the selector lines S₁₋ₙ based upon the received address. The BL decoder 406 is configured to selectively apply a signal (e.g., a current and/or a voltage) to one of the bit line pairs BL₁₁₋₂ₘ based upon the received address. The source lines SL₁₋ₘ are electrically coupled to support read circuitry (not shown) such as a multiplexer and/or an amplifier configured to determine an output of a read operation.

In accordance with various embodiments of the present disclosure, a subset of the MCs (e.g., the MCs disposed along a certain column) are each operatively (e.g., electrically) coupled to a pair of bit lines BL₁₁₋₂ₘ. Further, such a subset of the MCs are coupled to one another as a respective NAND memory string. Accordingly, the circuit 400 can include a plural number of NAND memory strings, each of which can include a number of MCs sharing a pair of BLs. For example, a first pair of bit lines BL₁₁ and BL₂₁ are electrically coupled to a number of the MCs (e.g., memory cells 100) that are coupled to one another as a first NAND memory string; a second pair of bit lines BL₁₂ and BL₂₂ are electrically coupled to a number of the MCs (e.g., memory cells 100) that are coupled to one another as a second NAND memory string; and so on. Specifically, one of the bit lines (first bit line) BL₁₁ is electrically coupled to a bit line write region (e.g., 112 of FIG. 1) that is shared by the MCs of the first NAND memory string, and the other of the bit lines (second bit line) BL₂₁ is electrically coupled to a bit line read region (e.g., 114 of FIG. 1) that is shared by the same MCs.

As such, the first BL₁₁ and/or the bit line write region (e.g., 112 of FIG. 1) may be utilized during a write operation (e.g., erase or program operation) to set a resistance value of the corresponding MC, such that FN tunneling occurs in the bit line write region (e.g., 112 of FIG. 1). During the write operation, an unselect bias voltage may be applied to the second bit line BL₂₁, such that the bit line read region (e.g., 114 of FIG. 1) is unselected. During a read operation performed on the MC, an unselect bias voltage is applied to the first bit line BL₁₁, such that the bit line write region (e.g., 112 of FIG. 1) is unselected. Thus, FN tunneling may not occur in the bit line read region (e.g., 114 of FIG. 1) during the write operation, thereby increasing an endurance and reliability of the MC. Operation of the MCs will be discussed in further detail below.

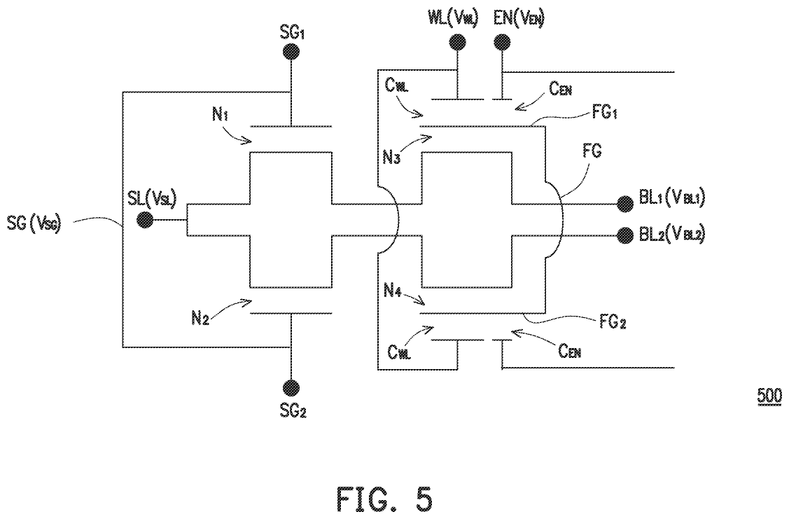

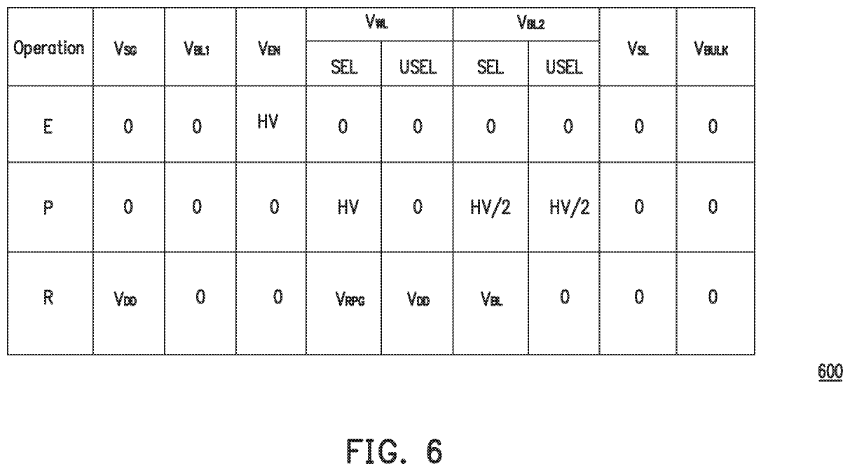

FIG. 5 illustrates an example circuit diagram 500 of the memory cell 100 of FIGS. 1-3 (e.g., an implementation of the MC of FIG. 4), and FIG. 6 illustrates a Table 600 corresponding to some operation conditions applied to one or more of the memory cells 100 of FIGS. 1-3 (e.g., one or more of the MCs of FIG. 4), in accordance with various embodiments.

Referring first to FIG. 5, a select gate SG includes a first select gate SG₁ and a second select gate SG₂ electrically coupled to one another. A select gate voltage V_{SG} may be applied to the select gate SG. A first select transistor N₁ includes the first select gate SG₁ and a second select transistor N₂ includes the second select gate SG₂. A first select source/drain region of the first select transistor N₁ and a first select source/drain region of the second select transistor N₂ are both electrically coupled to a source line SL. A source line voltage V_{SL} may be applied to the source line SL. A first storage source/drain region of a first storage transistor N₃ is electrically coupled to a second select source/drain region of the first select transistor N₁. A first storage source/drain region of a second storage transistor N₄ is directly electrically coupled to a second select source/drain region of the second select transistor N₂. A floating gate FG includes a first floating gate FG₁ and a second floating gate FG₂. The first storage transistor N₃ includes the first floating gate FG₁ and the second storage transistor N₄ includes the second floating gate FG₂. A second storage source/drain region of the first storage transistor N₃ is electrically coupled to a first bit line BL₁ (one of the bit lines in a corresponding bit line pair) and a second storage source/drain region of the second storage transistor N₄ is electrically coupled to a second bit line BL₂ (the other of the bit lines in the corresponding bit line pair). A first bit line voltage V_{BL1} may be applied to the first bit line BL₁ and a second bit line voltage V_{BL2} may be applied to the second bit line BL₂.

A first capacitor C_{EN} is disposed between the floating gate FG and an erase node (EN). In some embodiments, a first electrode of the first capacitor C_{EN} may be defined by first doped regions of a substrate (e.g., 110 of FIGS. 11 and/or 104 of FIG. 1) and a second electrode of the first capacitor C_{EN} may be defined by the floating gate FG. The first capacitor C_{EN} may, for example, be configured as a tunneling capacitor. An erase node voltage V_{EN} may be applied to the first electrode of the first capacitor C_{EN}. The erase node voltage V_{EN} may be applied to the first capacitor active region (e.g., 110 of FIG. 1). Further, the erase node voltage V_{EN} may be directly applied to the first well region (e.g., 104 of FIG. 1). The erase node voltage V_{EN} may, for example, be applied to the first electrode of the first capacitor C_{EN} by way of an erase line EL.

A second capacitor C_{WL} is disposed between the floating gate FG and a word line WL. A first electrode of the second capacitor C_{WL} may be defined by second doped regions of a substrate (e.g., 117 of FIGS. 1 and/or 108 of FIG. 1) and a second electrode of the second capacitor C_{WL} may be defined by the floating gate FG. The second capacitor C_{WL} may, for example, be configured has a coupling capacitor. A word line voltage V_{WL} may be applied to the first electrode of the second capacitor C_{WL}. The word line voltage V_{WL} may be applied to the third well region (e.g., 108 of FIG. 1). The word line voltage V_{WL} may be applied to the second capacitor active region (e.g., 117 of FIG. 1). The word line voltage V_{WL} may, for example, be applied to the first electrode of the second capacitor C_{WL} by way of a word line WL.

Referring next to FIG. 6, Table 600 illustrates various operating conditions of the disclosed memory cell 100 (configured, e.g., in the circuit diagram of FIG. 5), in accordance with various embodiments. The Table 600 includes three rows, which may correspond to an erase operation, a program operation, and a read operation performed on one or more of the memory cells 100, respectively.

During an erase operation, the select gate voltage V_{SG} applied to the select gate SG is about 0 volts (V). The word line voltage V_{WL} is, for example, about 0 V and may be applied to the third well region (e.g., 108 of FIG. 1). The erase node voltage V_{EN} is, for example, a high voltage (HV) and may be applied to the first well region (e.g., 104 of FIG. 1). In some embodiments, the HV may, for example, be within a range of about 7 to 10 V, within a range of about 10 to 18 V, within a range of about 7 to 18 V, or another suitable value. The first bit line voltage V_{BL1} (applied to 112 of FIG. 1) is, for example, about 0 V and may be applied to the second storage source/drain region of the first storage transistor N₃ (e.g., the first source/drain region 140 of FIG. 1). The second bit line voltage V_{BL2} (applied to 114 of FIG. 1) is, for example, about 0 V and may be applied to the second storage source/drain region of the second storage transistor N₄ (e.g., the fourth source/drain region 146 of FIG. 1). The source line voltage V_{SL} is about 0 V and may be applied to the first select source/drain region of the first and second select transistors N₁, N₂ (e.g., the third and sixth source/drain regions 144, 150 of FIG. 1). In some embodiments, a bulk substrate voltage V_{BULK} is about 0 V and may be applied to a bulk region of the substrate (e.g., 102 of FIG. 1). The bulk region of the substrate (e.g., 102 of FIG. 1) may be region(s) of the substrate that is/are offset from the first, second, and third well regions (e.g., 104, 106, 108 of FIG. 1). Under the aforementioned operating conditions, a voltage at the first capacitor C_{EN} is sufficiently high such that charge carriers (e.g., electrons) are discharged from the floating gate FG by FN tunneling to the first electrode of the first capacitor C_{EN} (e.g., the first well region 104 of FIG. 1 and/or the first capacitor active region 110 of FIG. 1). This in part erases a data state of the floating gate FG such that the floating gate FG is in a high resistance state. By virtue of utilizing FN tunneling to erase the floating gate FG, a power consumption of the MC may be reduced.

It should be noted that the circuit diagram 500 in FIG. 5 represents a single memory cell of a memory array, and the above-discussed erase operation corresponds to a selected (SEL) MC (e.g., one of the MCs coupled to the bit line pairs BL₁₁ and BL₂₁ of FIG. 4). Accordingly, during the erase operation, a first unselect bit line voltage is applied to a second storage source/drain of a first storage transistor of one or more unselected (USEL) MCs and a second unselect bit line voltage is applied to a second storage source/drain region of a second storage transistor of the one or more unselected MCs. In various embodiments, during the erase operation, the first unselect bit line voltage may be about 0 V and the second unselect bit line voltage may also be about 0 V. For example, in FIG. 4, an unselect bit line voltage applied to the bit lines BL₁₂ to BL₂ₘ may each be about 0 V, such the MCs coupled to the bit lines BL₁₂ to BL₂ₘ may not be erased by the erase operation performed on the selected MC.

During a program operation, the select gate voltage V_{SG} is about 0 V and may be applied to the select gate SG. The word line voltage V_{WL} is, for example, a high voltage (HV) and may be applied to the third well region (e.g., 108 of FIG. 1). In some embodiments, the HV may, for example, be within a range of about 7 to 10 V, within a range of about 10 to 18 V, within a range of about 7 to 18 V, or another suitable value. The erase node voltage V_{EN} may be, for example, 0 V and may be applied to the first well region (e.g., 104 of FIG. 1). The first bit line voltage V_{BL1} is, for example, about 0 V and may be applied to the second storage source/drain region of the first storage transistor N₃ (e.g., the first source/drain region 140 of FIG. 1). The second bit line voltage V_{BL2} is, for example, about half of the HV (e.g., about HV/2) and may be applied to the second storage source/drain region of the second storage transistor N₄ (e.g., the fourth source/drain region 146 of FIG. 1). The source line voltage V_{SL} is about 0 V and may be applied to the first select source/drain region of the first and second select transistors N₁, N₂ (e.g., the third and sixth source/drain regions 144, 150 of FIG. 1). In some embodiments, a bulk substrate voltage V_{BULK} is about 0 V and may be applied to a bulk region of the substrate (e.g., 102 of FIG. 1). Under the aforementioned operation conditions, by virtue of the HV being applied to the first and second capacitors C_{EN}, C_{WL} and about 0 V being applied to the first bit line BL₁, an inverse of the erase operation occurs, such that charge carriers (e.g., electrons) are injected from the second storage source/drain region of the first storage transistor N₃ by FN tunneling into the floating gate FG. In some embodiments, the charge carriers may be injected from the bit line write region (e.g., 112 of FIG. 1) and/or the second well region (e.g., 106 of FIG. 1). This in part programs a data state of the floating gate FG such that the floating gate FG is in a low resistance state. By virtue of utilizing FN tunneling to program the floating gate FG, a power consumption and a programming time (e.g., a write time) of the circuit 400 may be reduced. In further embodiments, if, for example, channel hot electrode (CHE) injection (not shown) is utilized to program the floating gate FG, a power consumption and programming time may be increased.

By virtue of applying about half of the HV (e.g., about HV/2) to the second storage source/drain region of the second storage transistor N₄ (e.g., the fourth source/drain region 146 of FIG. 1) during the program operation, the second storage transistor N₄ may be unselected during the program operation. This in turn eliminates and/or mitigates an injection of charge carriers from the second storage source/drain region of the second storage transistor N₄ into the floating gate FG. Thus, a segment of the dielectric structure (134 of FIGS. 2-3) underlying the second floating gate FG₂ may not be damaged by the FN tunneling. This increases a number of erase, write, and/or read operations that may be performed on the floating gate FG, thereby increasing a reliability and endurance of the circuit 400.

It should be noted that the circuit diagram 500 in FIG. 5 represents a single memory cell of a memory array, and the above-discussed program operation corresponds to a selected (SEL) MC (e.g., one of the MCs coupled to the bit line pairs BL₁₁ and BL₂₁ of FIG. 4). Accordingly, during the program operation, an unselect bit line voltage may be applied to one or more unselected (USEL) MCs. The unselect bit line voltage may, for example, be about half of the HV (e.g., about HV/2), such that the one or more unselected MCs are not programed. For example, in FIG. 4 and during the program operation, the unselect bit line voltage may be applied to the bit lines BL₁₂ to BL₂ₘ.

During a read operation, the select gate voltage V_{SG} is equal to VDD and may be applied to the select gate SG. In some embodiments, the voltage VDD may, for example, be about 2.5 V, 3.3 V, 5 V, 6V, or another suitable voltage such that the first and/or second select transistors N₁, N₂ are each in an ON state. The word line voltage V_{WL} is, for example, about 1.5 V and may be applied to the third well region (e.g., 108 of FIG. 1). The erase node voltage V_{EN} is, for example, about 0 V and may be applied to the first well region (e.g., 104 of FIG. 1). The first bit line voltage V_{BL1} is, for example, about 0 V and may be applied to the second storage source/drain region of the first storage transistor N₃ (e.g., the first source/drain region 140 of FIG. 1). The second bit line voltage V_{BL2} is, for example, about 0.3˜1.5 V and may be applied to the second storage source/drain region of the second storage transistor N₄ (e.g., the fourth source/drain region 146 of FIG. 1). In some embodiments, a bulk substrate voltage V_{BULK} is about 0 V and may be applied to a bulk region of the substrate (e.g., 102 of FIG. 1). Under the aforementioned operation conditions, a data state of the FG floating gate may be read at the source line SL. Because the second bit line voltage V_{BL2} is significantly less than a voltage applied for a program operation (e.g., the HV) damage to the segment of the dielectric structure (e.g., 134 of FIGS. 2-3) underlying the second floating gate FG₂ is eliminated and/or reduced during the read operation. By virtue of the bit line write region (e.g., 112 of FIG. 1) being laterally offset from the bit line read region (e.g., 114 of FIG. 1), the read operation may not be affected by the FN tunneling utilized during the program operation. This in turn reduces and/or eliminates a number of inaccurate read operations and increases a reliability and endurance of the memory cell.

It should be noted that the circuit diagram 500 in FIG. 5 represents a single memory cell of a memory array, and the above-discussed read operation corresponds to a selected (SEL) MC (e.g., one of the MCs coupled to the bit line pairs BL₁₁ and BL₂₁ of FIG. 4). Accordingly, during the read operation, an unselect bit line voltage may be applied to one or more unselected (USEL) MCs. The unselect bit line voltage may, for example, be about 0 V, such that the one or more unselected MCs are not read. For example, in FIG. 4 and during the read operation, the unselect bit line voltage may be applied to the bit lines BL₁₂ to BL₂ₘ.

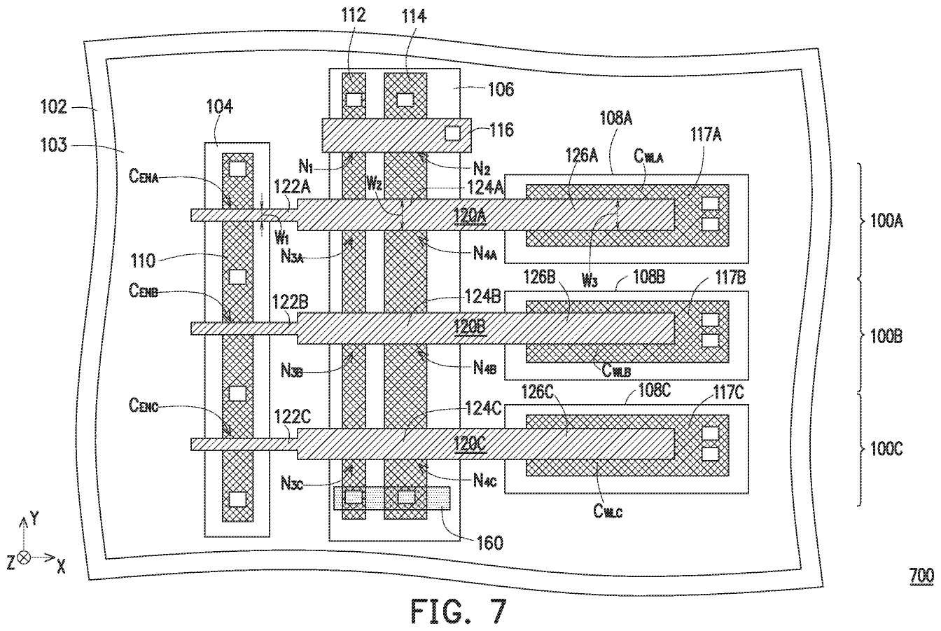

FIG. 7 illustrates an example layout of a NAND memory string 700 that includes a plural number of the above-discussed memory cells 100, in accordance with various embodiments. Although three memory cells (e.g., 100A, 100B, 100C) are shown in the example of FIG. 7, it should be understood the NAND memory string 700 can include any number of memory cells while remaining within the scope of the present disclosure. In some embodiments, each of the memory cells 100A to 100C is substantially similar to the memory cell 100 of FIG. 1, and thus, some of the reference numerals corresponding to the memory cell 100 will be reused in the following discussion.

As shown, the memory cells 100A to 100C (of a NAND memory string) may have their floating gates (FGs) 120A, 120B, and 120C, respectively, and their second capacitor active regions 117A, 117B, and 117C, respectively. The second capacitor active regions 117A to 117C may be disposed in their third well regions 108A, 108B, and 108C, respectively, in some embodiments. The memory cells 100A to 100C may share a common first capacitor active region, a common bit line write region, a common bit line read region, a common select gate (SG), and a common source line (SL). For example, the memory cells 100A to 100C may share the first capacitor active region 110, the bit line write region 112, the bit line read region 114, the SG 116, and the SL 160. Specifically, along the X direction, the FG 120A can extend from the shared first capacitor active region 110, through the shared bit line write region 112 and bit line read region 114, and to the corresponding second capacitor active region 117A; the FG 120B can extend from the shared first capacitor active region 110, through the shared bit line write region 112 and bit line read region 114, and to the corresponding second capacitor active region 117B; and the FG 120C can extend from the shared first capacitor active region 110, through the shared bit line write region 112 and bit line read region 114, and to the corresponding second capacitor active region 117C.

As such, the memory cells 100A to 100C may share the same select transistors N₁ (defined by the bit line write region 112 and the SG 116) and N₂ (defined by the bit line read region 114 and the SG 116), while having their respective storage transistors. For example, the memory cell 100A may have its first storage transistor N_{3A} defined by FG portion 124A and the bit line write region 112 and second storage transistor N_{4A} defined by FG portion 124A and the bit line read region 114; the memory cell 100B may have its first storage transistor N_{3B} defined by FG portion 124B and the bit line write region 112 and second storage transistor N_{4B} defined by FG portion 124B and the bit line read region 114; and the memory cell 100C may have its first storage transistor N_{3C} defined by FG portion 124C and the bit line write region 112 and second storage transistor N_{4A} defined by FG portion 124C and the bit line read region 114. In various embodiments, the respective first storage transistors N_{3A} to N_{3C} of the memory cells 100A to 100C may be serially coupled to one another (as a NAND memory string), and the respective second storage transistors N_{4A} to N_{4C} of the memory cells 100A to 100C may be serially coupled to one another (as the same NAND memory string).

Further, the memory cells 100A to 100C may have their respective first capacitors C_{EN}. For example, the memory cell 100A may have its first capacitors C_{ENA} defined at least by FG portion 122A and the shared first capacitor active region 110; the memory cell 100B may have its first capacitors C_{ENB} defined at least by FG portion 122B and the shared first capacitor active region 110; and the memory cell 100C may have its first capacitors C_{ENC} defined at least by FG portion 122C and the shared first capacitor active region 110. Still further, the memory cells 100A to 100C may have their respective second capacitors C_{WL}. For example, the memory cell 100A may have its second capacitors C_{WLA} defined at least by FG portion 126A and the respective second capacitor active region 117A; the memory cell 100B may have its second capacitors C_{WLB} defined at least by FG portion 126B and the respective second capacitor active region 117B; and the memory cell 100C may have its second capacitors C_{WLC} defined at least by FG portion 126C and the respective second capacitor active region 117C.

In some embodiments, the different portions of each of the FGs 120A to 120C may have different widths along the Y direction. For example, the portion 122A/B/C, that overlies the first capacitor active region 110, may have a first width W₁, the portion 124A/B/C, that overlies the bit line write region 112 and the bit line read region 114, may have a second width W₂, and the portion 126A/B/C, that overlies the second capacitor active region 117, may have a third width W₃. The first width W₁ is less than the second width W₂, and the second width W₂ is equal to (as shown in FIG. 7) or less than (as shown in FIG. 1) the third width W₃.

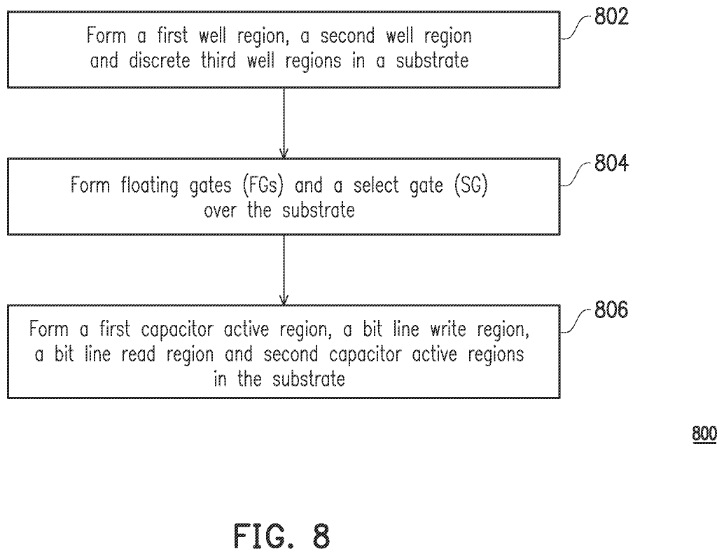

FIG. 8 illustrates a flow chart of an example method 800 for forming a memory device, in accordance with various embodiments. The memory device, made the method 800, may include a NAND memory string with a number of the disclosed memory cells (e.g., the memory string 700 of FIG. 7). In some embodiments, the method 800 can form the memory device based on the layout discussed above. Accordingly, some of the reference numerals above may be used in the following discussion.

While the method 800 of FIG. 8 is illustrated and described herein as a series of operations, it should be appreciated that the illustrated ordering of such operations is not to be interpreted in a limiting sense. For example, some operations may occur in different orders and/or concurrently with other operations apart from those illustrated and/or described herein. Further, not all illustrated operations may be required to implement one or more aspects or embodiments of the present disclosure herein, and one or more of the operations depicted herein may be carried out in one or more separate operations and/or phases.

The method 800 starts with operation 802 in which a first well region, a second well region, and a number of discrete third well regions are formed in a substrate, in accordance with various embodiments. For example in FIG. 7, a first well region (e.g., 104), a second well region (e.g., 106), and a number of third well regions (e.g., 108A-C) are formed along a frontside surface of a substrate (e.g., 102). The first well region 104, the second well region 106, and the third well regions 108A-C may be laterally spaced from one another along the X direction, with the second well region 106 is interposed between the first well region 104 and the third well regions 108A-C. Further, the third well regions 108A-C are laterally spaced from one another along the Y direction. In some embodiments, the first well region 104 and the third well regions 108A-C may have a first conductive type, and the second well region 106 may have a second, opposite conductive type.

It should be noted that prior to forming the multiple well regions in the substrate, a number of isolation regions (e.g., STIs) can be formed along the frontside surface of the substrate (e.g., partially extending into the substrate from the frontside surface) to define respective footprints of the first well region 104, the second well region 106, and the third well regions 108A-C. As such, the well regions can be formed by one or more respective ion implantation processes. The one or more selective ion implantation processes may each include: forming a masking layer (not shown) over the frontside surface of the substrate 102 and selectively implanting ions in the substrate 102 according to the masking layer. For example, the first well region 104 and the third well regions 108A-C that have the same first conductive type may be concurrently formed based on a first masking layer, and the second well region that has the second conductive type may be formed based on a second masking layer.

The method 800 proceeds to operation 804 in which a number of floating gates (FGs) and a select gate (SG) are formed over the substrate, in accordance with various embodiments. Continuing with the above example, plural FGs (e.g., 120A-C) and a single SG (e.g., 116), each of which extends along the X direction, can be formed over the substrate 102. In some embodiments, the SG 116 may extend across the second well region 106, while each of the FGs 120A-C may extend across the first well region 104, the second well region 106, and a corresponding one of the third well regions 108A-C. Specifically, the FG 120A extends from the first well region 104, through the second well region 106, and to the third well region 108A; the FG 120B extends from the first well region 104, through the second well region 106, and to the third well region 108B; and the FG 120C extends from the first well region 104, through the second well region 106, and to the third well region 108C.

Prior to forming the FGs 120A-C and SG 116, a gate dielectric material may be first deposited (by, e.g., CVD, PVD, ALD, thermal oxidation, or another suitable deposition or growth process) over the substrate, followed by at least another deposition process (by, e.g., CVD, PVD, ALD, sputtering, or another suitable growth or deposition process) of a gate electrode material. The gate dielectric material can include at least one of silicon dioxide, a high-k dielectric material, or another suitable dielectric material, and the gate electrode material can include at least one of polysilicon such as intrinsic polysilicon and/or doped polysilicon, aluminum, or another suitable conductive material. Next, the gate dielectric material and the gate electrode material are patterned to form the FGs 120A-C and SG 116, and their corresponding gate dielectric structures (e.g., 134, 152).

The method 800 proceeds to operation 806 in which a first capacitor active region, a bit line write region, a bit line read region, and a number of second capacitor active regions are formed in the substrate, in accordance with various embodiments. Still with the above example, a first capacitor active region (e.g., 110) is formed in the first well region 104, a bit line write region (e.g., 112) and a bit line read region (e.g., 114) are formed in the second well region 106, and a number of second capacitor active regions (e.g., 117A to 117C) are formed in the third well regions 108A to 108C, respectively.

Upon forming the first capacitor active region, the bit line write region, the bit line read region, and the second capacitor active regions, a number of capacitors and a number of transistors can be defined. Further, a number of memory cells, each including four transistors (first and second storage transistors, and first and second select transistors) and two capacitors (first and second storage capacitors), can be formed as a NAND memory string based on those capacitors and transistors being defined, in various embodiments.

For example in FIG. 7, the memory cells 100A to 100C that share the same select transistors N₁ (defined by the bit line write region 112 and the SG 116) and N₂ (defined by the bit line read region 114 and the SG 116) can be formed. The memory cell 100A can further have its first storage transistor N_{3A} defined by FG portion 124A and the bit line write region 112 and second storage transistor N_{4A} defined by FG portion 124A and the bit line read region 114; the memory cell 100B can further have its first storage transistor N_{3B} defined by FG portion 124B and the bit line write region 112 and second storage transistor N_{4B} defined by FG portion 124B and the bit line read region 114; and the memory cell 100C can further have its first storage transistor N_{3C} defined by FG portion 124C and the bit line write region 112 and second storage transistor N_{4A} defined by FG portion 124C and the bit line read region 114. In addition, the respective first storage transistors N_{3A} to N_{3C} of the memory cells 100A to 100C are serially coupled to one another (as a NAND memory string), and the respective second storage transistors N_{4A} to N_{4C} of the memory cells 100A to 100C are serially coupled to one another (as the same NAND memory string).

In one aspect of the present disclosure, a memory device is disclosed. The memory device includes a first well region, a second well region, and a plurality of third well regions disposed within a substrate, wherein the second well region is interposed between the first region and the plurality of third well regions along a first lateral direction, and wherein the plurality of third well regions are separated from one another along a second lateral direction perpendicular to the first lateral direction. The memory device includes a plurality of floating gates disposed over the first to third well regions, wherein each of the plurality of floating gates continuously extends from the first well region to a corresponding one of the third well regions along the first lateral direction. The memory device includes a bit line write region disposed within the second well region, wherein the bit line write region comprises first source/drain regions disposed on opposite sides of each of the plurality of floating gates. The memory device includes a bit line read region disposed within the second well region and spaced from the bit line write region along the first lateral direction, wherein the bit line read region comprises second source/drain regions disposed on the opposite sides of each of the plurality of floating gates.

In another aspect of the present disclosure, a memory device is disclosed. The memory device includes a plurality of non-volatile memory cells operatively coupled to one another as a NAND memory string. Each of the plurality of non-volatile memory cells includes a first capacitor including a first plate formed at least of a doped region within a first well region and a second plate formed of a first portion of a corresponding one of a plurality of floating gates; a second capacitor including a first plate formed at least of a doped region within a corresponding one of a plurality of third well regions and a second plate formed of a second portion of the corresponding one of the plurality of floating gates; a first storage transistor including first source/drain regions disposed within a bit line write region and a first gate electrode formed of a third portion of the corresponding one of the plurality of floating gates; and a second storage transistor including second source/drain regions disposed within a bit line read region and a second gate electrode formed of a fourth portion of the corresponding one of the plurality of floating gates. The bit line read region and the bit line write region are disposed in a second well region and are laterally spaced from each other along a first lateral direction.

In yet another aspect of the present disclosure, a method for forming a memory device is disclosed. The method includes doping a substrate to form a first well region, a second well region, and a plurality of third well regions within the substrate, wherein the second well region is interposed between the first well region and the plurality of third well regions along a first lateral direction. The method includes doping the substrate to form a bit line read region and a bit line write region within the second well region, wherein the bit line read region is spaced from the bit line write region along the first lateral direction. The method includes forming a plurality of floating gates over the substrate, wherein each of the plurality of floating gates continuously extends from the first well region to a corresponding one of the third well regions along the first lateral direction.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a first well region, a second well region, and a plurality of third well regions disposed within a substrate, wherein the second well region is interposed between the first region and the plurality of third well regions along a first lateral direction, and wherein the plurality of third well regions are separated from one another along a second lateral direction perpendicular to the first lateral direction;
a plurality of floating gates disposed over the first to third well regions, wherein each of the plurality of floating gates continuously extends from the first well region to a corresponding one of the third well regions along the first lateral direction;
a bit line write region disposed within the second well region, wherein the bit line write region comprises first source/drain regions disposed on opposite sides of each of the plurality of floating gates; and
a bit line read region disposed within the second well region and spaced from the bit line write region along the first lateral direction, wherein the bit line read region comprises second source/drain regions disposed on the opposite sides of each of the plurality of floating gates.

2. The memory device of claim 1, wherein, along the first lateral direction, a width of the bit line write region is less than a width of the bit line read region.

3. The memory device of claim 1, wherein, along the second lateral direction, each of the floating gates has a first width over the first well region, a second width over the second well region, and a third width over each of the third well regions, wherein the first width is less than the second width and the second width is less than or equal to the third width.

4. The memory device of claim 1, further comprising an isolation structure disposed within a front-side surface of the substrate, wherein the isolation structure laterally surrounds the first well region, the second well region, and the third well regions.

5. The memory device of claim 1, further comprising a plurality of dielectric structures disposed between the substrate and a corresponding one of the plurality of floating gates.

6. The memory device of claim 1, further comprising a single select gate continuously extending across the bit line write region and the bit line read region.

7. The memory device of claim 1, wherein each of the floating gates and a corresponding pair of the first source/drain regions operatively function as a first storage transistor of a corresponding one of a plurality of memory cells, and each of the floating gates and a corresponding pair of the second source/drain regions operatively function as a second storage transistor of the corresponding memory cell.

8. The memory device of claim 7, wherein each of the floating gates and at least one of a doped region in the first well region or the first well region operatively function as a first plate and a second plate of a first capacitor of the corresponding memory cell, respectively.

9. The semiconductor device of claim 8, wherein each of the floating gates and at least one of a doped region in each of the third well regions or the corresponding third well region operatively function as a first plate and a second plate of a second capacitor of the corresponding memory cell, respectively.

10. The memory device of claim 9, wherein the plurality of memory cells and operatively coupled to one another as a NAND memory string.

11. A memory device, comprising:
a plurality of non-volatile memory cells operatively coupled to one another as a NAND memory string;
wherein each of the plurality of non-volatile memory cells comprises:
a first capacitor including a first plate formed at least of a doped region within a first well region and a second plate formed of a first portion of a corresponding one of a plurality of floating gates;
a second capacitor including a first plate formed at least of a doped region within a corresponding one of a plurality of third well regions and a second plate formed of a second portion of the corresponding one of the plurality of floating gates;
a first storage transistor including first source/drain regions disposed within a bit line write region and a first gate electrode formed of a third portion of the corresponding one of the plurality of floating gates; and
a second storage transistor including second source/drain regions disposed within a bit line read region and a second gate electrode formed of a fourth portion of the corresponding one of the plurality of floating gates;
wherein the bit line read region and the bit line write region are disposed in a second well region and are laterally spaced from each other along a first lateral direction.

12. The memory device of claim 11, wherein the second well region is interposed between the first well region and the third well region along the first lateral direction.

13. The memory device of claim 11, wherein the plurality of third well regions are spaced from one another along a second lateral direction perpendicular to the first lateral direction.

14. The memory device of claim 11, wherein, along a second lateral direction perpendicular to the first lateral direction, the first portion, the second portion, the third portion, and the fourth portion of each of the floating gates have a first width, a second width, a third width, and a fourth width, respectively, and wherein the first width is less than the third width, which is equal to the fourth width, which is equal to or less than the second width.

15. The memory device of claim 11, wherein the plurality of non-volatile memory cells, formed as the NAND memory string, share a first select transistor and a second select transistor.

16. The memory device of claim 15, wherein the first select transistor includes third source/drain regions disposed within the bit line write region and a third gate electrode formed of a first portion of a single select gate, and the second select transistor includes fourth source/drain regions disposed within the bit line read region and a fourth gate electrode formed of a second portion of the single select gate.

17. The memory device of claim 11, wherein the plurality of non-volatile memory cells, formed as the NAND memory string, share the bit line read region and the bit line write region.

18. A method for forming a memory device, comprising:
doping a substrate to form a first well region, a second well region, and a plurality of third well regions within the substrate, wherein the second well region is interposed between the first well region and the plurality of third well regions along a first lateral direction;
doping the substrate to form a bit line read region and a bit line write region within the second well region, wherein the bit line read region is spaced from the bit line write region along the first lateral direction; and
forming a plurality of floating gates over the substrate, wherein each of the plurality of floating gates continuously extends from the first well region to a corresponding one of the third well regions along the first lateral direction.

19. The method of claim 18, wherein the plurality of third well regions are spaced from one another along a second lateral direction perpendicular to the first lateral direction.

20. The method of claim 19, further comprising forming a select gate over the substrate, wherein the select gate is spaced from the plurality of floating gates along the second lateral direction and extends across the bit line read region and the bit line write region.
